(19) United States
(12) Patent Application Publication
(10) Pub. No.: US 2008/0054277 A1
(43) Pub. Date: Mar. 6, 2008

(54) SEMICONDUCTOR LASER DEVICE

(75) Inventors: Masayoshi Takemi, Tokyo (JP); Kenichi Ono, Tokyo (JP); Yoshihiko Hanamaki, Tokyo (JP); Chikara Watatani, Tokyo (JP); Tetsuya Yagi, Tokyo (JP); Harumi Nishiguchi, Tokyo (JP); Motoko Sasaki, Tokyo (JP); Shinji Abe, Tokyo (JP); Yasuaki Yoshida, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI DENKI KABUSHIKI KAISHA, Tokyo (JP)

(21) Appl. No.: 11/923,751

(22) Filed: Oct. 25, 2007

Related U.S. Application Data
(62) Division of application No. 10/732,351, filed on Dec. 11, 2003.

(30) Foreign Application Priority Data
Dec. 13, 2002 (JP) 2002-362007
Jul. 17, 2003 (JP) 2003-276127

(51) Int. Cl. H01L 27/15

(52) U.S. Cl. 257/85; 257/E27.12

(57) ABSTRACT

The semiconductor laser device includes an active layer, a p-type cladding layer, and a p-type cap layer. The layers are sequentially stacked so that the semiconductor laser device is provided. The p-type cap layer includes both a p-type dopant and an n-type dopant. In another aspect, the p-type cap layer includes a first layer including a first p-type dopant and a second layer including a second p-type dopant having a diffusion coefficient smaller than that of the first p-type dopant. The first layer is far from the active layer, and the second layer is close to the active layer. In further aspect, the p-type cap layer includes carbon (C) as a p-type dopant. According to these configuration, the p-type dopant can be prevented from being diffused in the active layer and the p-type cladding layer.

### BACKGROUND OF THE INVENTION

1. Field of the Invention

The present invention relates to a semiconductor laser device which is improved in light-emitting characteristics by reducing a resistance of the device.

2. Description of the Related Art

In recent years, an amount information which must be processed by an information communication machine is vast. Therefore, the demand for a recording device operated at a high speed and a large-capacity recording medium are increasing. In a DVD-R drive device which is one of such recording devices, a high-output and high-efficient semiconductor laser is used. This device records information on a DVD-R serving as a large-capacity recording medium by using a semiconductor laser and reads out the recorded information.

Since further demands for a high speed and a large capacity are possessed in the field of future information communication, a high-output and high-efficient semiconductor laser is necessary. In fact, an AlGaInP-based semiconductor laser of output 140 mW to 200 mW class is being developed.

The structure of a semiconductor laser will be described below. An AlGaInP-based laser immediately after crystal growth is constituted by sequentially laminating a buffer layer (GaAs/AlGaAs), an n-type cladding layer (AlGaInP), a well layer (GaInP), a barrier layer (AlGaInP), an MQW active layer, a p-type cladding layer (AlGaInP), and a p-type GaAs cap layer (contact layer) on an n-type GaAs layer substrate. Such a structure is fabricated by a crystal growing method such as an MOCVD (Metalorganic Chemical Vapor Deposition) method or an MBE (Molecular Beam Epitaxy) method. As a p-type dopant, Zn which is one of the group-II elements is used. Electrodes are arranged on the upper and lower sides of the structure described above, so that a semiconductor laser device is obtained.

In order to obtain a high-output and high-efficient semiconductor laser, the contact resistance of the semiconductor laser must be reduced. The carrier concentration of a p-type GaAs cap layer (contact layer) is set to be high to reduce the contact resistance of the device.

For example, Japanese Laid-open Patent Publication No. H11-54828 describes a semiconductor laser device constituted by a compound semiconductor obtained by separately doping Zn or Si into a cap layer (contact layer). Japanese Laid-open Patent Publication No. H9-51140 describes a semiconductor laser having a p-type ZnSe cap layer. In these semiconductor laser devices, Zn and Se are not used as p-type dopants. Japanese Laid-open Patent Publication No. 2002-261321 discloses a technique for doping C at a predetermined concentration. This C functions as a barrier for suppressing other impurities such as Zn and the like from being diffused.

Zn serving as a p-type dopant has a tendency to be easily diffused in a growth process or a thermal treatment process. For this reason, in a conventional structure in which a p-type GaAs cap layer is doped with Zn at a high concentration, Zn is disadvantageously diffused to an active layer which essentially serves as an undoped layer. When an active layer which essentially serves as an undoped layer is doped, problems such as deterioration of crystal quality, a reduction in emission intensity, and movement (difference from a design value) of a p-n junction position are posed. For this reason, a semiconductor laser having preferable emitting characteristics can not obtain. As a cause of diffusion of Zn, the following is considered. That is, for example, in GaAs, Zn₊₁ located at an interstitial position is coupled with a hole at a Ga position which is a group-III element or excludes a Ga atom to the interstitial position to tend to occupy the Ga position.

Although Mg which is used as a p-type dopant like Zn has a degree of diffusion which is lower than that of Zn, Mg is saturated at a concentration of about 1.0×10¹⁸ cm⁻³ in doping. For this reason, Mg cannot be easily achieve high-concentration doping which must be performed to reduce a contact resistance.

### SUMMARY OF THE INVENTION

It is an object of the present invention to prevent or suppress a p-type dopant of a p-type GaAs layer which is doped at a high concentration from being diffused in an active layer to obtain a contact layer having a high carrier concentration and, conclusively, to obtain a high-output and high-efficient semiconductor laser device having a reduced device resistance.

In accordance with one aspect of the present invention, there is a semiconductor laser device in which an active layer, a p-type cladding layer, and a p-type cap layer are sequentially stacked. The p-type cap layer includes both a p-type dopant and an n-type dopant.

In another aspect of the present invention, there is a semiconductor laser device in which an active layer, a p-type cladding layer, and a p-type cap layer are sequentially stacked. The p-type cap layer includes a first layer having a first p-type dopant and a second layer having a second p-type dopant having a diffusion coefficient smaller than that of the first p-type dopant. The first layer is far from the active layer and the second layer is close to the active layer.

In a further aspect of the present invention, there is a semiconductor laser device including an active layer, a p-type cladding layer, and a p-type cap layer. The layers are sequentially stacked, and the p-type cap layer includes at least carbon (C) as a p-type dopant.

In the semiconductor laser device according to the present invention, an active layer, a p-type cladding layer, and a p-type cap layer are sequentially stacked, and the p-type cap layer includes both a p-type dopant and an n-type dopant. In this manner, the p-type dopant is prevented from being diffused in the active layer and the p-type cladding layer, so that the semiconductor laser device can efficiently emit light with a high output power.

In another semiconductor laser device according to the present invention, an active layer, a p-type cladding layer, and a p-type cap layer are sequentially stacked, and the p-type cap layer includes a first layer which is formed by a first p-type dopant and is far from an active layer and a second layer which is formed by a second p-type dopant having a diffusion coefficient smaller than that of the first p-type dopant and which is close to the active layer. In this manner, the p-type dopant is prevented from being diffused in the active layer and the p-type cladding layer, so that the semiconductor laser device can efficiently emit light with a high output power.

In still another semiconductor laser device according to the present invention, an active layer, a p-type cladding layer, and a p-type cap layer are sequentially stacked, and the p-type cap layer includes carbon (C) as a p-type dopant. Carbon (c) has a small diffusion coefficient, and is not easily diffused even if C is doped at a high concentration. Therefore, the p-type dopant can be suppressed from being diffused in an active layer and a p-type cladding layer. Therefore, the semiconductor laser device can efficiently emit light with a high output power.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1A is a cross sectional view of the semiconductor laser device according to the first embodiment;

FIG. 1B is a cross sectional view of the configuration of the cap layer according to the first embodiment;

FIG. 2A is a cross sectional view of the semiconductor laser device according to the second embodiment;

FIG. 2B is a cross sectional view of the configuration of the cap layer according to the second embodiment;

FIG. 3A is a cross sectional view of the semiconductor laser device according to the third embodiment;

FIG. 3B is a cross sectional view of the configuration of the cap layer according to the third embodiment;

FIG. 4A is a cross sectional view of the semiconductor laser device according to the fourth embodiment;

FIG. 4B is a cross sectional view of the configuration of the cap layer according to the fourth embodiment;

FIG. 5A is a cross sectional view of the semiconductor laser device according to the fifth embodiment;

FIG. 5B is a cross sectional view of the configuration of the cap layer according to the fifth embodiment;

FIG. 6 is a diagram of an example of the structure of a semiconductor laser device according to the present invention.

FIG. 7A is a cross sectional view of the semiconductor laser device according to the sixth embodiment;

FIG. 7B is a cross sectional view of the configuration of the cap layer according to the sixth embodiment;

FIG. 8 is a graph of relationship between an element concentration and a depth from the surface of the semiconductor laser device of the sixth embodiment;

FIG. 9 is a graph of relationship between an element concentration and a depth from the surface of the conventional semiconductor laser device having a cap layer including zinc (Zn);

FIG. 10 is a graph of relationship between a flow ratio V/III of tri-methyl gallium/arsine and a concentration of carbon included in the cap layer;

FIG. 11A is a cross sectional view of the semiconductor laser device according to the seventh embodiment; and

FIG. 11B is a cross sectional view of the configuration of the cap layer according to the seventh embodiment.

### DETAILED DESCRIPTION OF THE PREFERRED EMBODIMENTS

Embodiments of the present invention will be described below with reference to the accompanying drawings. The constituent elements numbered the same reference numeral in the drawings denote the constituent elements having a same function.

### First Embodiment

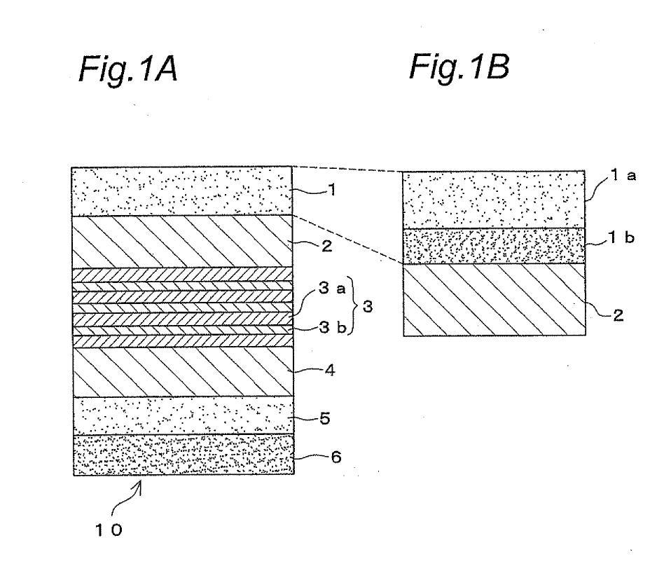

FIG. 1A is a cross sectional view of a semiconductor laser device 10 according to the first embodiment. The semiconductor laser device 10 is a so-called AlGaInP-based laser, and is designed to prevent and suppress zinc (Zn) of a cap layer doped at a high concentration from being diffused in an active layer.

The detailed configuration is as follows. The semiconductor laser device 10 includes a p-type GaAs cap layer 1, a p-type cladding layer 2 (AlGaInP) a multi-quantum-well (MQW) active layer 3, an n-type cladding layer 4 (AlGaInP), a buffer layer 5 (GaAs/AlGaAs), and an n-type GaAs substrate 6. These layers are sequentially stacked on the n-type GaAs substrate 6 from the buffer layer 5 in the reverse order using a crystal growth method such as a metal organic chemical vapor deposition (MOCVD) method or a molecular beam epitaxy (MBE) method. FIG. 1A shows a structure obtained immediately after the crystal growth.

The p-type GaAs cap layer 1 is doped with Zn at a high concentration. The multi-quantum-well active layer 3 is a layer formed by a multi-quantum-well structure. The multi-quantum-well structure is obtained by laminating a large number of quantum-well structures each of which is obtained by sandwiching a small well layer 3b (well layer; GaInP) having a small band gap between barrier layers 3a (AlGaInP) having a large band gap. According to this structure, emission efficiency can be improved.

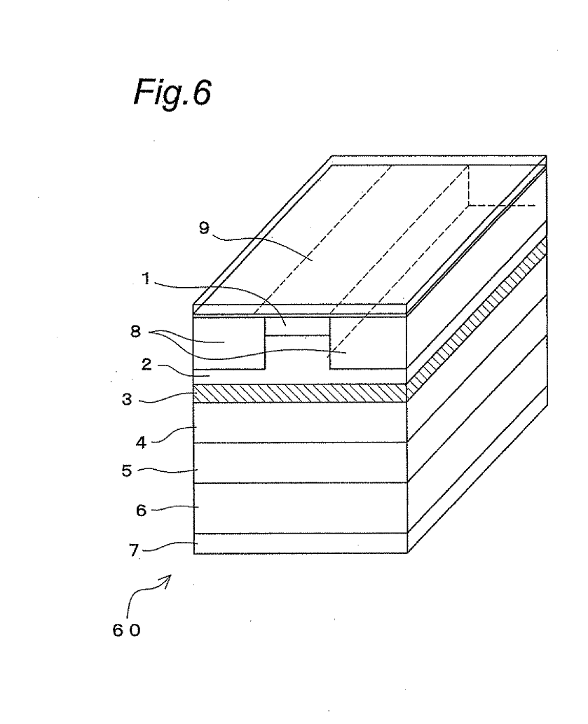

On the surface of the substrate 6 opposing the buffer layer 5 and the surface of the cap layer 1 opposing the p-type cladding layer 2, electrodes (not shown) are arranged. The electrodes supply holes and electrons for causing the semiconductor laser device to emit light. The holes and electrons are coupled to each other in the multi-quantum-well active layer 3 to emit light. An example of the finished semiconductor laser device is shown in FIG. 6. FIG. 6 is a diagram of a semiconductor laser device 60. It is understood that an n-type electrode 7 and a p-type electrode 9 are formed on the lower end and the upper end of the semiconductor laser device 60. The other components correspond to the layers denoted by the same reference numerals in FIG. 1A. The semiconductor laser device 60 is a laser device which is so-called current constriction structure having an n-type current block layer 8. In order to form the n-type current block layer 8, p-type cladding layers 2 are formed in the form of stripes through a step such as an etching step and the like. By using these components, a laser device having improved emission efficiency can be obtained. As will be described below, the scope of application of this embodiment is not limited to a laser device having a current constriction structure.

FIG. 1B is a cross sectional view of the configuration of the p-type GaAs cap layer 1 according to the first embodiment. In this embodiment, the cap layer 1 is constituted by two layers. More specifically, a mixed doped layer (Zn+Zi-GaAs layer) 1b obtained by doping both a p-type dopant (Zinc (Zn)) and an n-type dopant (Silicon (Si)) in the p-type GaAs cap layer 1 on the side close to the multi-quantum-well active layer 3 (a side which contact with the p-type cladding layer 2) is formed, and a single doped layer (Zn—GaAs layer) 1a obtained by singularly doping a p-type dopant (Zn) in the upper side of the Zn+Si—GaAs layer 1b (a side far from the active layer 3). It is to be noted that the Zn+Si—GaAs layer 1b is formed as a p-type layer. Although Zn and Si are known as a p-type dopant and an n-type dopant respectively, a concentration of Zn is adjusted to be higher than a concentration of Si in this embodiment, the layer 1b entirely serves as a p-type layer. On the other hand, the Zn—GaAs layer 1a is formed by doping Zn at a high concentration, therefor Zn is present at a high concentration near the surface of the p-type GaAs layer 1. Therefore, a contact resistance which is an important factor for increasing the output and efficiency of the semiconductor laser can be reduced.

Zn which is generally used as a p-type dopant has a tendency to be easily diffused. On the other hand, it is considered that Zn is not easily diffused in a region in which Si is doped at a high concentration. This is because (1) Si used as an n-type dopant also occupies a Ga position and becomes Si⁺_{Ga} and (2) and it is considered that, since both Zn⁺_{I} located at an interstitial position and Si⁺_{Ga} located at a Ga position are positively charged, Coulomb repulsion is generated between Zn⁺_{I} and Si⁺_{Ga}. More specifically, it is because the polarities of ionization of the p-type dopant and the n-type dopant are equal to each other.

In the cap layer 1 having the above configuration, the Zn+Si—GaAs layer 1b doped with Zn and Si are arranged on the active layer 3 side of the cap layer doped with Zn at a high concentration. For this reason, Zn doped in the upper Zn—GaAs layer 1a can be suppressed by the effect of the Coulomb repulsion from being diffused in the active layer 3.

### Second Embodiment

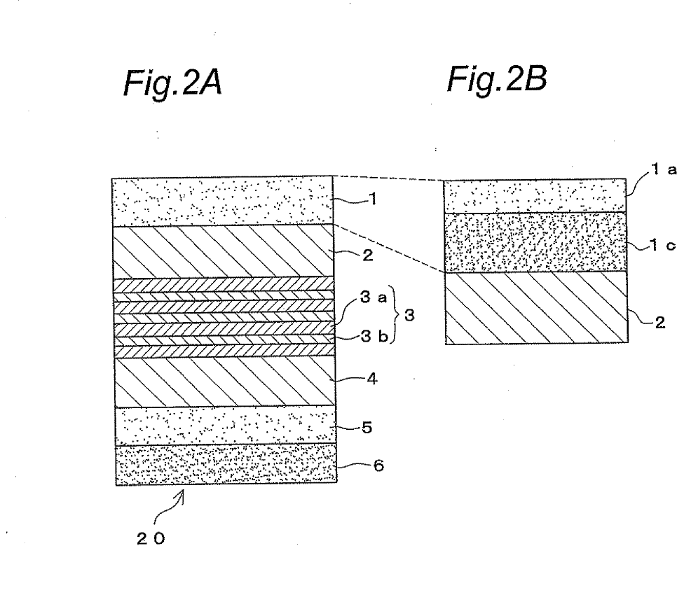

FIG. 2A is a cross sectional view of a semiconductor laser device 20 according to the second embodiment. The semiconductor laser device 20 is also designed such that Zn in a cap layer doped with Zn at a high concentration is prevented and suppressed from being diffused in an active layer. The layer structure of the semiconductor laser device 20 is the same as the layer structure of the semiconductor laser device 10 except for the configuration of a cap layer 1. The semiconductor laser device 20 can also be realized as the semiconductor laser device 60 shown in FIG. 6. Since these contents are the same as those described in the first embodiment except for the following points, the description thereof will be omitted.

The semiconductor laser device 20 is different from the semiconductor laser device 10 (FIGS. 1A and 1B) in that the cap layer has an Mg—GaAs layer 1c in place of the Zn+Si—GaAs layer 1b (FIG. 1B). FIG. 2B is a cross sectional view of the configuration of the cap layer 1 according to the second embodiment. As is understood from FIG. 2B, the Mg—GaAs layer 1c doped with magnesium (Mg) is formed on the active layer 3 side of the cap layer 1, and a Zn—GaAs layer 1a is formed on the upper side (opposite side of the active layer 3) of the cap layer 1.

The reason why the Mg—GaAs layer 1c is formed using Mg serving as a p-type dopant like Zn is that a p-type dopant (Zn, Mg) can be prevented from being diffused in the active layer 3 by doping Mg because Mg has a diffusion coefficient smaller than that of Zn. On the other hand, since the semiconductor laser device 20 has the Zn—GaAs layer 1a doped with Zn at a high concentration, as in the first embodiment, a contact resistance can be reduced to realize a high-output and high-efficient laser. Although it is difficult to dope at a high concentration to reduce a contact resistance by applying Mg alone, when the Zn—GaAs layer 1a and the Mg—GaAs layer 1c coexist, diffusion of the p-type dopant into the active layer 3 can be reduced, and the contact resistance can also be reduced.

### Third Embodiment

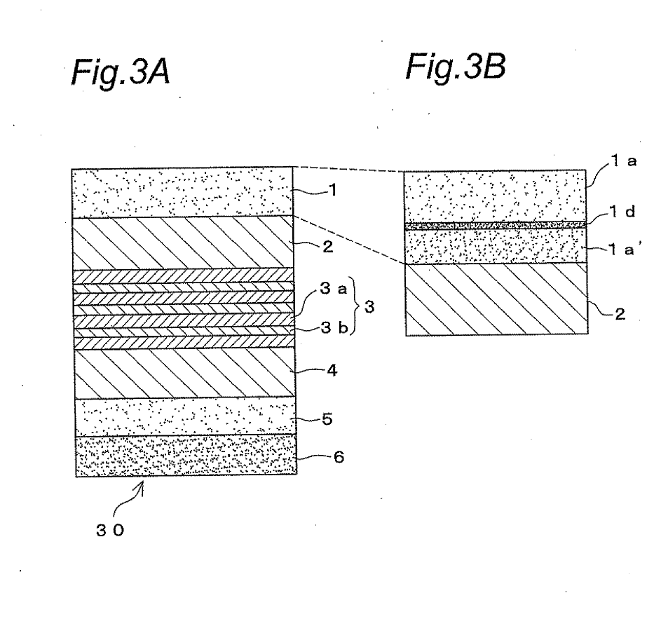

FIG. 3A is a cross sectional view of a semiconductor laser device 30 according to the third embodiment. The semiconductor laser device 30 is also designed such that Zn in a cap layer doped at a high concentration is prevented and suppressed from being diffused in an active layer. The layer structure of the semiconductor laser device 30 is the same as that of the semiconductor laser device 10 except for the configuration of the cap layer 1. The semiconductor laser device 30 can also be realized as the semiconductor laser device 60 shown in FIG. 6. Since these contents are the same as those described in the first embodiment except for the following points, a description thereof will be omitted.

The semiconductor laser device 30 is different from the semiconductor laser device 10 (FIG. 1) in that the cap layer 1 is constituted by a Zn—GaAs layer 1a, a Zn+Se—GaAs layer Id, and a Zn—GaAs layer 1a′ which are sequentially stacked from the upper surface side of the cap layer 1. FIG. 3B is a cross sectional view of the configuration of the cap layer 1 according to the third embodiment. As is understood from FIG. 3B, the Zn+Se—GaAs layer 1d is formed between the Zn—GaAs layers 1a and 1a′. In other words, the Zn+Se—GaAs layer Id is formed like dividing the Zn—GaAs layers. A region Id doped with Zn and selenium (Se) has a concentration of Zn which is higher than a concentration of Se, and entirely serves as a p-type region.

The reason why the Zn+Se—GaAs layer 1d is formed is to prevent Zn doped in a region 1a′ on an active layer side from being diffused in an active layer 3 side. Although Zn serving as a p-type dopant generally has a tendency to be easily diffused, Zn is diffused easier in the GaAs layer id than in the active layer 3 side for the following reason. That is, since Se is generally used as an n-type dopant and is a group-VI element, Se easily occupies the position of As which is a group-V element in GaAs. In this case, Se has negative charges. It is considered that Zn is easily diffused in a region doped with Se for the following reasons. That is, Se occupies a lattice position different from that of Zn (Zn occupies a (Se—As)Ga position), and Coulombic attraction acts between Se and Zn because Se located at a Ga position is negatively charged and because Zn is positively charged. Therefore, the Zn+Se—GaAs layer 1d is formed, so that Zn doped in the region 1a′ on the active layer 3 side can be prevented from being diffused in the active layer 3.

### Fourth Embodiment

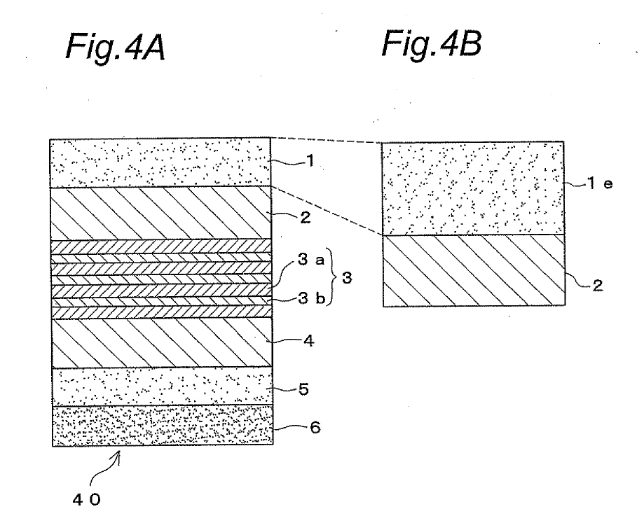

FIG. 4A is a cross sectional view of a semiconductor laser device 40 according to the fourth embodiment. The semiconductor laser device 40 is also designed such that a p-type dopant doped in a cap layer at a high concentration is prevented and suppressed from being diffused in an active layer. The layer structure of the semiconductor laser device 40 is the same as that of the semiconductor laser device 10 except for the configuration of the cap layer 1. The semiconductor laser device 40 can also be realized as the semiconductor laser device 60 shown in FIG. 6. Since these contents are the same as those described in the first embodiment except for the following points, a description thereof will be omitted.

The reason why the semiconductor laser device 60 is different from the semiconductor laser device 10 (FIG. 1) in that the cap layer 1 is constituted by a p-type GaAs layer 1e doped with carbon (C) and having a high carrier concentration. FIG. 4B is a cross sectional view of the configuration of the cap layer 1 according to the fourth embodiment. Carbon is doped by receiving intermediate products in a decomposition process of organometal materials by optimization of growth conditions such as a reduction in a V/III ratio or by an organometal material such as CBr₄ in growth of crystal.

The reason why the C—GaAs layer 1e is employed is that C has a small diffusion coefficient and is not easily diffused in the active layer even though C is doped at a high concentration. When C is doped, diffusion of the p-type dopant into the active layer 3 can be reduced while keeping the high carrier concentration of the p-type GaAs cap layer 1.

### Fifth Embodiment

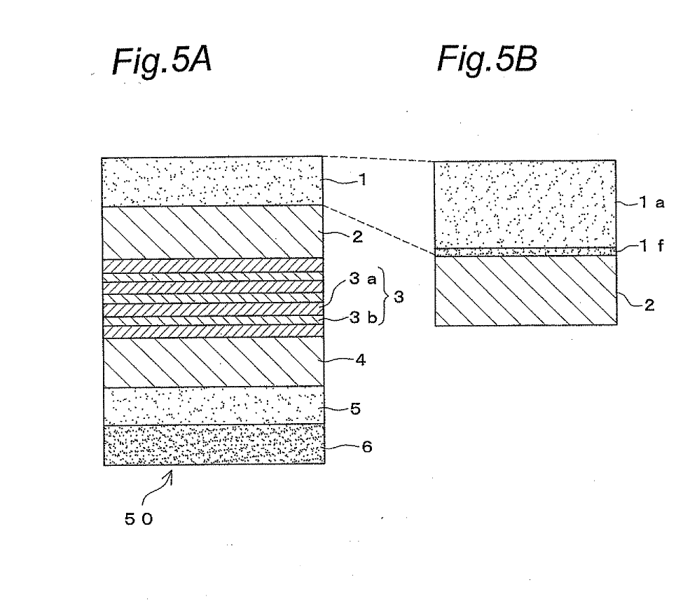

FIG. 5A is a cross sectional view of a semiconductor laser device 50 according to the fifth embodiment. The semiconductor laser device 50 is also designed such that a p-type dopant doped in a cap layer at a high concentration is prevented and suppressed from being diffused in an active layer. The layer structure of the semiconductor laser device 50 is the same as that of the semiconductor laser device 10 except for the configuration of the cap layer 1. The semiconductor laser device 50 can also be realized as the semiconductor laser device 60 shown in FIG. 6. Since these contents are the same as those described in the first embodiment except for the following points, a description thereof will be omitted.

The semiconductor laser device 50 is different from the semiconductor laser device 10 (FIGS. 1A and 1B) in that the cap layer 1 has an n-type GaAs layer If in place of the Zn+Si—GaAs layer 1b (FIG. 1B). FIG. 5B is a cross sectional view of the configuration of the cap layer 1 according to the fifth embodiment. The n-type GaAs layer If doped with an n-type dopant such as Si or Se is originally formed on the active layer 3 side of the cap layer 1, and a Zn—GaAs layer 1a is formed on the upper side (opposite side of the active layer 3) of the cap layer 1. The GaAs layer If is obtained by growing crystal after a p-type cladding layer 2 is formed. The GaAs layer if has a thickness and a carrier concentration which are compensated by Zn diffused from the Zn—GaAs layer 1a and which are set such that the GaAs layer If can be changed into a p-type layer. More specifically, the characteristics of the GaAs layer if are compensated by Zn diffused from the Zn—GaAs layer 1a, and the original n-type changes into a p-type.

When Zn doped in the Zn—GaAs layer 1a on the upper side (opposite side of the active layer 3) of the cap layer is diffused in the n-type GaAs layer 1f on the lower side (p-type cladding layer 2 side), a diffusion rate of Zn which is downwardly diffused from the n-type GaAs layer If reduced while carriers are compensated. Therefore, when the thickness of the n-type GaAs layer 1f and the concentration of the n-type dopant are adjusted, Zn doped in the Zn—GaAs layer 1a on the upper side of the cap layer at a high concentration can be prevented and suppressed from being diffused in the active layer 3.

The embodiments of the present invention have been described above. In the first embodiment (FIGS. 1A and 1B) and the third embodiment (FIGS. 3A and 3B) described above, the example using Zn as a p-type dopant was explained. However, when the structures explained in the respective embodiments are employed, even if a different element is used as a p-type dopant, the dopant can be prevented and suppressed from being diffused in the active layer 3. For example, in place of Zn, an element (Mg, beryllium (Be), cadmium (Cd), or the like) which is a group-II element and which occupies a Ga position can be used. When these elements are doped in the cap layer 1 together with Si or Se, the above advantage can be achieved. In place of Si in the Zn+Si—GaAs layer 1b (FIGS. 1A and 1B) in the first embodiment, carbon (C), tin (Sn), or the like which is a group-IV element like Si and which has positive charges when the element occupies a Ga position may be used. These elements and a p-type dopant such as Zn are simultaneously doped, the same advantage as described above can be obtained.

### Sixth Embodiment

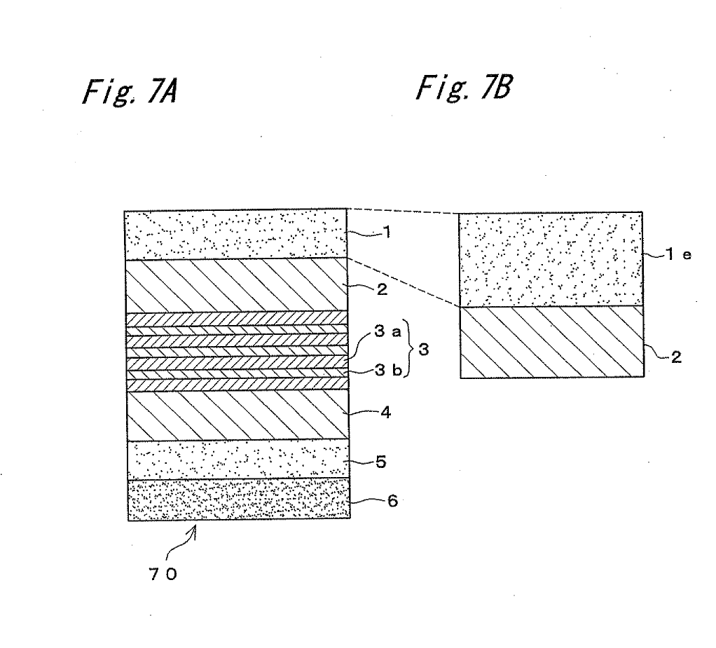

FIG. 7A is a cross sectional view of a semiconductor laser device 50 according to the sixth embodiment. The semiconductor laser device has a n-type GaAs substrate, and includes a n-type GaAs buffer layer 5, a n-type AlGaInP cladding layer 4, a multiple quantum wells (MQW) active layer 3, a p-type AlGaInP cladding layer 2, and a p-type GaAs cap layer (contact layer) 1a, which are sequentially deposited. The n-type GaAs buffer layer 5 includes silicon (Si) which is n-type dopant, and also may include an AlGaAs layer. The n-type AlGaInP cladding layer 4 includes silicon which is n-type dopant. The MQW active layer 3 has an AlGaInP optical guide layer which has no dopant, an AlGaInPb barrier layer 3a, and a GaInP well layer 3b, the layers are repeatedly deposited. The p-type AlGaInP cladding layer 2 includes magnesium which is p-type dopant. The p-type GaAs cap layer 1e includes carbon which is p-type dopant. It is noted that the semiconductor laser device may be a embedded laser device having a current constriction structure or a laser device having a ridge waveguide structure.

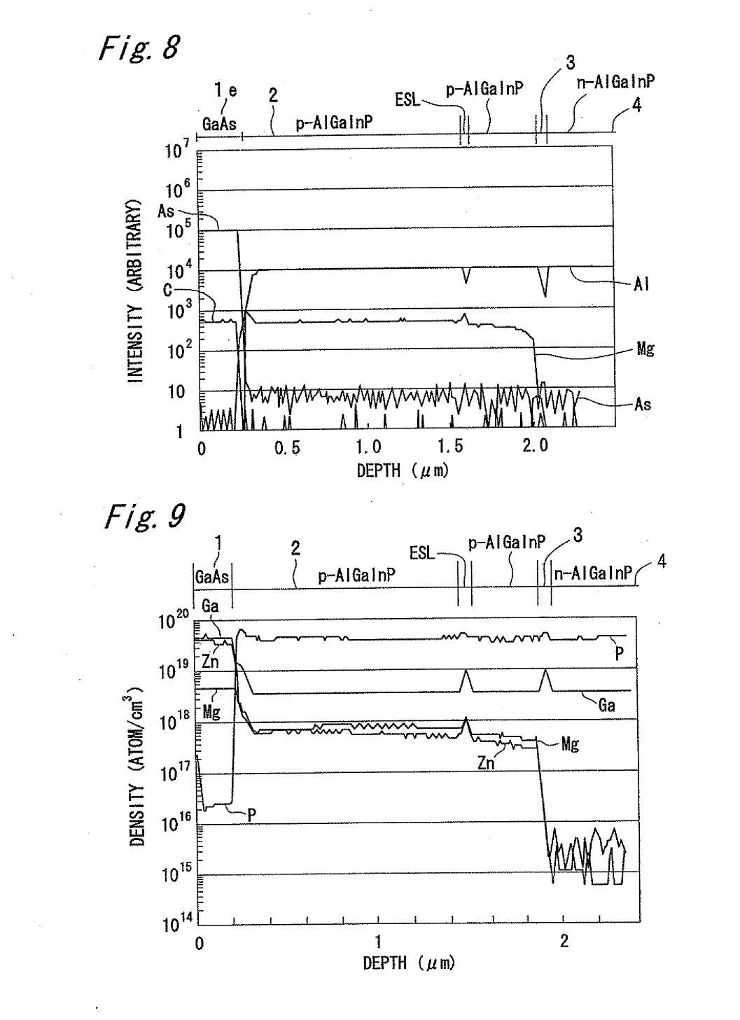

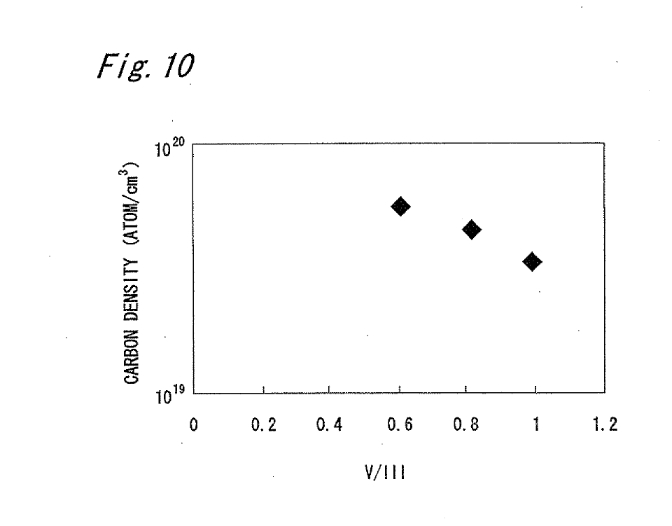

FIG. 8 is a graph of relationship between an element concentration and a depth from the surface of the semiconductor laser device of the sixth embodiment. Each element concentration is detected by using secondary ion-mass spectrography while sputtering the surface of the semiconductor laser device. In FIG. 8, the longitudinal axis denotes depth from the surface of the semiconductor laser device, and the vertical axis denotes intensity (arbitrary unit) corresponding to the element concentration. It is noted that the depth can be measured by the sputtering time. An etching stopper layer (ESL) is inserted in the middle of the p-type AlGaInP cladding layer 2. The etching stopper layer is provided so as to stop the etching at the middle of the p-type AlGaInP cladding layer 2, when the ridge waveguide structure is constructed.

FIG. 9 is a graph of relationship between an element concentration and a depth from the surface of the conventional semiconductor laser device having a cap layer including zinc (Zn). In FIG. 9, the longitudinal axis and the vertical axis are same as mentioned in FIG. 8 As shown in FIG. 9, zinc doped in the GaAs cap layer 1 and magnesium doped in the AlGaInP cladding layer are diffused over the active layer 3 in the conventional semiconductor laser device. Meanwhile, carbon doped as p-type dopant in the GaAs cap layer 1e and magnesium doped in the p-type AlGaInP cladding layer 2 adjacent to the GaAs cap layer 1e is not diffused each other in this embodiment of the present invention. Additionally, comparing with using zinc and magnesium as dopant, carbon doped as p-type dopant in the GaAs cap layer 1e is not diffused over the active layer 3.

The concentration of carbon doped in the GaAs cap layer will be noted as follows. The concentration of carbon as p-type dopant is preferably more than 10¹⁹ cm⁻³ for high carrier concentration so that the contact resistance can be reduced. Even though the carbon is doped as p-type dopant having a higher concentration in the GaAs cap layer, the carbon is not diffused over the active layer 3 while maintaining high carrier concentration in the cap layer 1e. Therefore, the semiconductor laser device having high power and high performance can be provided.

Method of fabricating the semiconductor laser device is noted as follows. For example, n-type GaAs buffer layer 5, n-type AlGaInP cladding layer 4, multiple quantum well layer 3, p-type AlGaInP cladding layer 2, p-type GaAs cap layer (contact layer) 1a are deposited in turn on the n-type GaAs substrate by using any thin film deposition methods such as MOCVD so that the 5 semiconductor laser device can be provided.

MOCVD can be performed at growth temperature, e.g. 700° C., growth pressure, e.g. 100 mbar (100 hPa). Regarding with source gas used in MOCVD, e.g. trimethyl-indium (TMI) gas, trimethyl-gallium (TMG) gas, trimethyl-aluminum (TMA) gas, phosphine (PH₃) gas, arsine (AsH₃) gas, silane (SiH₄) gas, cyclopentadienyl-magnesium (Cp₂Mg) can be used. The source gases are flow controlled by mass flow controller so that desired composition is deposited.

The p-type GaAs cap layer 1e, in which the carbon is doped, is deposited by MOCVD at growth temperature, e.g. more than 542° C., at flow ratio (V/III) of arsine gas/trimethyl gallium gas higher than 0.6, preferably 1.0. On the other hand, in the conventional method, the GaAs layer is deposited at growth temperature ranging from 600° C. to 750° C., and at flow ratio of V/III ranging from 10 to several hundreds by MOCVD. Comparing with the conventional method, carbon derived from a methyl group of trimethylgallium is doped as p-type dopant in the GaAs cap layer without using any specific dopant materials. The above doping method without any specific dopant materials is referred as intrinsic doping method (F. Brunner, J. Crystal Growth 221 (2000), pp53-58). It is noted that a conventional doping method using tetra-bromide carbon as dopant of carbon may be used instead of the intrinsic doping method in the GaAs cap layer.

### Seventh Embodiment

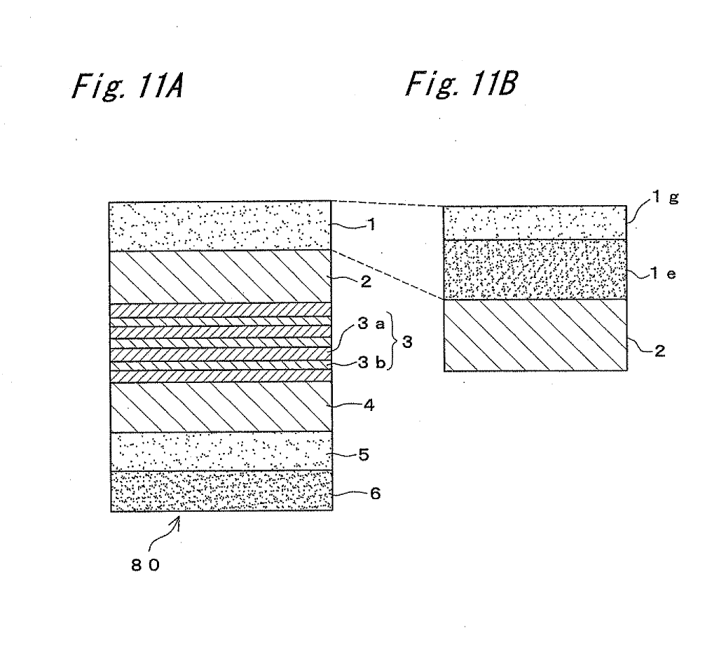

FIG. 11A is a cross sectional view of the semiconductor laser device according to the seventh embodiment, and FIG. 11B is a cross sectional view of the configuration of the cap layer according to the seventh embodiment. The semiconductor laser device 80 is different from the semiconductor laser device of the sixth embodiment in that a p-type GaAs cap layer 1e and a p-type InGaAs cap layer 1g are deposited in turn on the p-type AlGaInP cladding layer 2. In this case, carbon is doped in the p-type GaAs cap layer 1e and the p-type InGaAs cap layer 1g respectively as a p-type dopant. Magnesium is doped in the p-type AlGaInP cladding layer 2 as a p-type dopant. Then, the carbon of the GaAs cap layer 1e adjacent to the cladding layer 2, and the magnesium doped in the cladding layer 2 is not diffused each other. Also, the carbon and the magnesium is not diffused over the active layer. Since the InGaAs layer 1g has a forbidden band width narrower than that of the GaAs layer, the InGaAs layer has a higher conductivity than that of the GaAs layer at same dopant amount so that the InGaAs layer has good electric contact with an electrode. Therefore, the resistance of the device can be reduced. The InGaAs layer has good electric contact with the electrode, since the carrier concentration can be increased easily in the InGaAs layer. It is noted that the p-type InGaAs layer 1g has a composition formula of InₓGa₁₋ₓAs, preferably, x=0.5. The InGaAs layer 1g also has a mismatch of the lattice constant for the GaAs layer 1e, e.g. the lattice constant of InAs at x=1 is 7% longer than that of the GaAs layer. Then, a compressive strain is caused by the mismatch of the lattice constant, when the InGaAs layer 1g and the GaAs layer 1e are stacked, then, preferably, x=0.5. Also, the thickness of the InGaAs layer 1g is preferably thinner than 100 nm.

Although the present invention has been described in connection with the preferred embodiments thereof with reference to the accompanying drawings, it is to be noted that various changes and modifications are apparent to those skilled in the art. Such changes and modifications are to be understood as included within the scope of the present invention as defined by the appended claims, unless they depart therefrom.

1-10. (canceled)

11. A semiconductor laser device comprising:
a GaAs substrate;
an active layer;
a p-type AlGaInP cladding layer containing Mg as a dopant producing p-type conductivty;
a p-type GaAs cap layer containing carbon as a dopant producing p-type conductivity; and
an electrode in contact with the p-type GaAs cap layer, wherein the active, p-type cladding, and p-type cap layers are sequentially stacked and supported by the GaAs substrate.

12. The semiconductor laser device according to claim 11, wherein the p-type GaAs cap layer includes carbon a concentration higher than 10¹⁹ cm⁻³.

13 and 14. (canceled)

15. The semiconductor laser device according to claim 11, wherein the p-type cladding contacts the p-type GaAs cap layer.
